(19) United States
(12) Patent Application Publication
(10) Pub. No.: US 2013/0221431 A1
(43) Pub. Date: Aug. 29, 2013

(54) SEMICONDUCTOR DEVICE AND METHOD OF MANUFACTURE THEREOF

(71) Applicants: Yuta MUSHA, Saitama-ken (JP); Takayuki SAKAI, Ishikawa-ken (JP); Hideki OKUMURA, Kanagawa-ken (JP); Takahiro KAWANO, Kanagawa-ken (JP)

(72) Inventors: Yuta MUSHA, Saitama-ken (JP); Takayuki SAKAI, Ishikawa-ken (JP); Hideki OKUMURA, Kanagawa-ken (JP); Takahiro KAWANO, Kanagawa-ken (JP)

(73) Assignee: KABUSHIKI KAISHA TOSHIBA, Tokyo (JP)

(21) Appl. No.: 13/605,769

(22) Filed: Sep. 6, 2012

(30) Foreign Application Priority Data
Feb. 29, 2012 (JP) 2012-044158

(51) Int. Cl. H01L 29/78

(52) U.S. Cl. CPC H01L 29/7827
USPC 257/330; 438/270

(57) ABSTRACT

A method for manufacturing a semiconductor device includes forming a first insulating film on inner surfaces of trenches arranged in parallel in a semiconductor layer, forming a control electrode on the first insulating film, and forming a second insulating film on the control electrode, where the upper surface of the second insulating film is lower than the upper end of the first insulating film. In addition, the method includes etching the semiconductor layer to a depth near the upper end of the control electrode and forming a first semiconductor region. The method further includes forming a conductive film and then a second semiconductor region in the upper portion of the first semiconductor region by diffusion of impurities from the conductive film into the upper portion of the first semiconductor region, and forming a contact hole by etching back the conductive layer.

### CROSS-REFERENCE TO RELATED APPLICATION

This application is based upon and claims the benefit of priority from Japanese Patent Application No. 2012-044158, filed Feb. 29, 2012; the entire contents of which are incorporated herein by reference.

### FIELD

Embodiments described herein relate to a semiconductor device and its manufacturing method.

### BACKGROUND

In order to decrease the ON-state resistance of power semiconductor devices, chip structures have become more miniaturized. For example, in a MOSFET (metal oxide semiconductor field effect transistor) having a trench gate structure, a decrease in the ON-state resistance of the MOSFET may be achieved by decreasing the gate interval to make it possible for an increase in the channel width.

However, the miniaturization of the chip structure requires a high-precision process of photolithography, thus raising the manufacturing costs. Accordingly, a manufacturing method using the so-called self-alignment technique, independent of photolithography, is desirable.

### DESCRIPTION OF THE DRAWINGS

FIG. 1 is a schematic cross-section of a semiconductor device according to an embodiment.

FIGS. 2A to 2C are schematic cross-sections of the semiconductor device at various steps of manufacturing.

FIGS. 3A and 3B are schematic cross-sections of the semiconductor device at various steps of manufacturing subsequent to those shown in FIGS. 2A to 2C.

FIGS. 4A and 4B are schematic cross-sections of the semiconductor device at various steps of manufacturing subsequent to those shown in FIGS. 3A and 3B.

FIGS. 5A and 5B are schematic cross-sections of the semiconductor device at various steps of manufacturing subsequent to those shown in FIGS. 4A and 4B.

FIGS. 6A and 6B are schematic cross-sections of the semiconductor device at various steps of manufacturing subsequent to those shown in FIGS. 5A and 5B.

FIGS. 7A and 7B are schematic cross-sections of the semiconductor device at various steps of manufacturing subsequent to those shown in FIGS. 6A and 6B.

FIGS. 8A and 8B are schematic cross-sections of the semiconductor device at various steps of manufacturing subsequent to those shown in FIGS. 7A and 7B.

FIGS. 9A and 9B are schematic cross-sections of the semiconductor device at various steps of manufacturing subsequent to those shown in FIGS. 8A and 8B.

FIGS. 10A to 10C are schematic diagrams showing wafer cross-sections during manufacturing of the semiconductor device.

FIG. 11 is a schematic cross-section of the semiconductor device during an etching process.

### DETAILED DESCRIPTION

In general, each embodiment of the present disclosure will be explained with reference to the figures. As used herein, the same reference numbers will be used for the same parts in the figures, so their detailed explanation will be omitted. However, different parts will be explained separately. In the following embodiments, n and p conductive types maybe referred to as a first conductive type and second conductive type, or vise versa. In addition, X-Y orthogonal coordinates described in the figures will be referenced accordingly in the description.

Embodiments described herein provide a semiconductor device having a trench gate structure, which is formed by self-alignment, and its manufacturing method.

The method for manufacturing a semiconductor device according to one embodiment includes a process for forming a first insulating film on inner surfaces of trenches arranged in parallel in a first conductive type semiconductor layer, a process for forming a control electrode on the first insulating film in each of the trenches, and a process for forming a second insulating film on the control electrode, such that the upper surface of the second insulating film is at a position lower than an upper end of the first insulating film extending along the wall surfaces of the trenches. In addition, this method further includes a process for etching the semiconductor layer between adjacent trenches to a depth near an upper surface of the control electrode and a process for forming a first semiconductor region of a second conductive type that extends from the surface of the semiconductor layer to a depth between an upper end of the control electrode and a lower end of the control electrode. Moreover, this method further includes a process for forming a first conductive type conductive layer for covering the first insulating film, second insulating film, and first semiconductor region, and forming a second semiconductor region in the upper part of the first semiconductor region, into which first conductive type impurities are diffused, as well as a process for forming a contact hole on the surface of the second semiconductor region by etching back the first conductive type conductive layer.

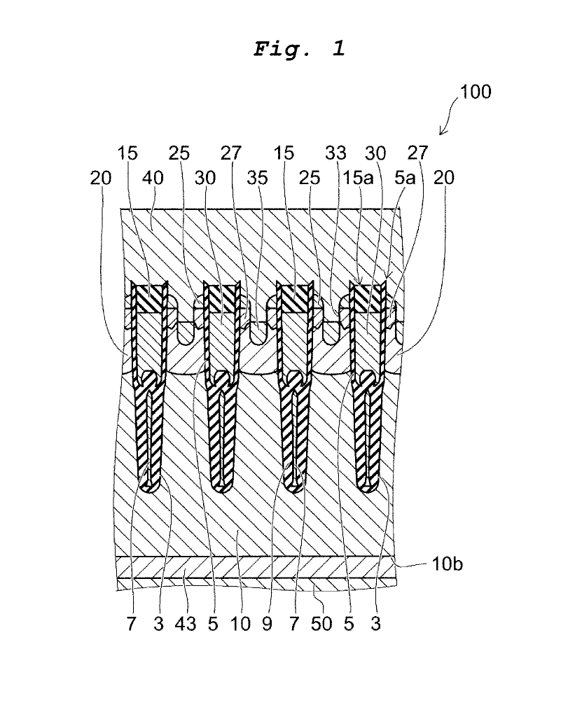

FIG. 1 is a schematic cross-section of a semiconductor device 100 according to an embodiment. The semiconductor device 100, for example, is a power MOSFET having a trench gate structure and can be formed using a silicon wafer. For example, a wafer in which an n type silicon layer with a low concentration is epitaxially grown on an n type silicon wafer may beused.

In the following explanation, an example in which the semiconductor device is manufactured using a silicon wafer will be shown, but embodiments are not limited such usage. For example, a compound semiconductor such as silicon carbide (SiC) and gallium nitride (GaN) may also be used.

The semiconductor device 100, for example, is provided with an n type drift layer 10 (semiconductor layer) as an n type silicon layer and a p type base region 20 (first semiconductor region). The p type base region 20 is installed on the n type drift layer 10. In addition, a gate electrode 30 (first control electrode) is prepared in a trenches 3 which extend through the p type base region 20 into n type drift layer 10. A gate insulating film 5 (first insulating film) installed on the inner surface of the trenches 3 is disposed between each gate electrode 30 and the p type base region 20. The trenches 3, for example, are formed in a stripe shape extending in the depth direction of FIG. 1.

The semiconductor device 100 is further provided with an n type source region 27 (second semiconductor region) installed on the p type base region 20, and a p type contact region 35 (third semiconductor region). The p type contact region 35 is selectively installed on the bottom face of a contact hole 33 installed in the n type source region 27.

In addition, a field plate electrode 7 (second control electrode) is installed between the bottom of the trench 3 and the gate electrode 30. The field plate electrode 7 faces the n type drift layer 10 via a field plate insulating film 9.

Moreover, in the contact hole 33, a source electrode 40 is formed so as to be in contact with the n type source region 27 and the p type contact region 35. The source electrode 40 covers an insulating film 15 (second insulating film) formed on the gate electrode 30, a gate insulating film 5, a portion of which is located on the side surface of the insulating film 15, and an n type polysilicon layer 25 (conductive layer) installed on the n type source region 27. On the bottom side, a drain electrode 50 is formed on the lower surface of the n type drift layer 10. The drain electrode 50 is electrically connected to the n type drift layer 10 via an n type drain layer 43 in contact with a lower surface 10b of then type drift layer 10.

In this embodiment, the gate insulating film 5 extends upward along the side surface of the insulating film 15, and its upper end 5a protrudes above an upper surface 15a of the insulating film 15. As will be evident from the description below, the formation of the contact hole 33 is made easy thereby.

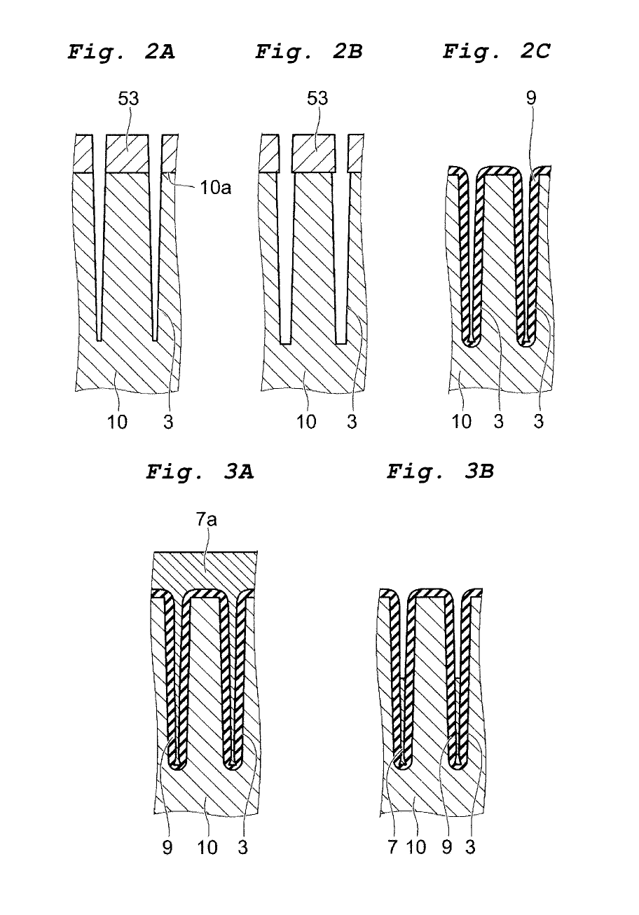

Next, the method for manufacturing the semiconductor device 100 will be explained with reference to FIGS. 2A to 9B. FIGS. 2A to 9B are schematic cross-sections of the semiconductor device 100 during manufacturing.

As shown in FIG. 2A, trenches 3 are formed in the n type semiconductor layer 10. The n type semiconductor layer 10, for example, is an n type silicon layer with a thickness of 5-10 μm and an impurity concentration of 1×10¹⁶ to 3×10¹⁶ cm⁻³.

On an upper surface 10a of the n type semiconductor layer 10, for example, an etching mask 53 composed of a silicon oxide film is formed, and several trenches 3 are formed by the RIE (reactive ion etching) method. The trenches 3 are installed in parallel along the upper surface 10a of the n type semiconductor layer 10 and formed in a stripe shape extending in the depth direction of FIG. 2A, for instance. The spacing between the aperture of adjacent trenches 3, for example, is 1 μm or smaller.

Next, as shown in FIG. 2B, the inner surface of the trench 3, for example, is etched by CDE (chemical dry etching) method to extend its width. Therefore, a damaged layer resulting from the RIE process on the inner surfaces of the trenches 3 can be removed. As a result, the width of the trench 3, for example, is 0.3-1.0 μm, and its depth D_{T} is 1-10 μm.

Next, the etching mask 53 is removed and a field plate insulating film 9 for covering the inner surfaces of the trenches 3 is formed as shown in FIG. 2C. The field plate insulating film 9, for example, is a silicon oxide film (SiO₂ film) formed by thermally oxidizing the n type semiconductor layer 10 (n type silicon layer) at the inner surfaces of the trenches 3 to a thickness of 50-300 nm.

Next, as shown in FIG. 3A, a polysilicon layer (polycrystalline silicon layer) 7a is filled inside the trenches 3. The polysilicon layer 7a, for example, is formed by the CVD (chemical vapor deposition) method. In addition, n type impurities are diffused into the polysilicon layer 7a to render electric conductivity.

Next, as shown in FIG. 3B, the polysilicon layer 7a is etched back to form a field plate electrode 7 in the lower part of the trench 3. In the etching of the polysilicon layer 7a, the CDE method may be employed.

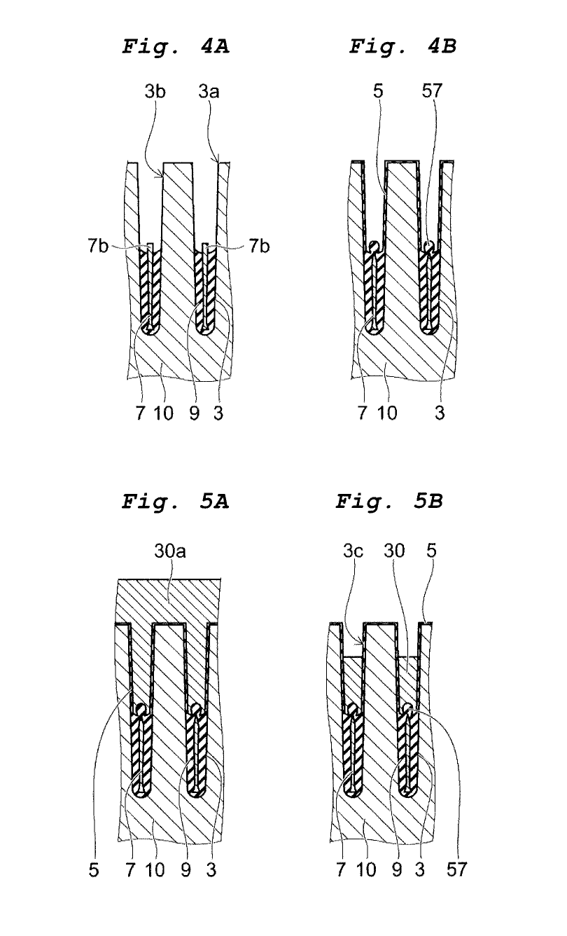

Next, as shown in FIG. 4A, each field plate insulating film 9 between an aperture 3a of the trench 3 and the field plate electrode 7, for example, is removed by wet-etching, exposing an upper end 7b of the field plate electrode 7.

Next, as shown in FIG. 4B, the gate insulating film 5 (first insulating film) is formed on the wall surfaces 3b of the upper part of the trenches 3. The gate insulating film 5 may be, for example, a silicon oxide film formed by thermally oxidizing the n type semiconductor layer 10 at the wall surface 3b. In addition, the thickness of the gate insulating film 7 is less than the field plate insulating film 9. At the same time, the upper end 7b of the field plate electrodes 7 are also thermally oxidized, forming an insulating layer 57 around upper ends 7b.

Next, as shown in FIG. 5A, a polysilicon layer (polycrystalline silicon layer) 30a is filled in the upper part of the trenches 3. The polysilicon layer 30a may be formed, for example, using the CVD method. In addition, n type impurities are diffused into the polysilicon layer 30a to provide electrical conductivity.

Next, as shown in FIG. 5B, the polysilicon layer 30a is etched back to form a gate electrode 30 on each field plate electrode 7. The polysilicon layer 30a is etched back up to a prescribed depth in the trench 3. Therefore, a space 3c is formed above each gate electrode 30. In addition, the gate insulating film is interposed between the gate electrode 30 and the n type semiconductor layer 10. The field plate electrode 7 and the gate electrode 30 are insulated by the insulating layer 57.

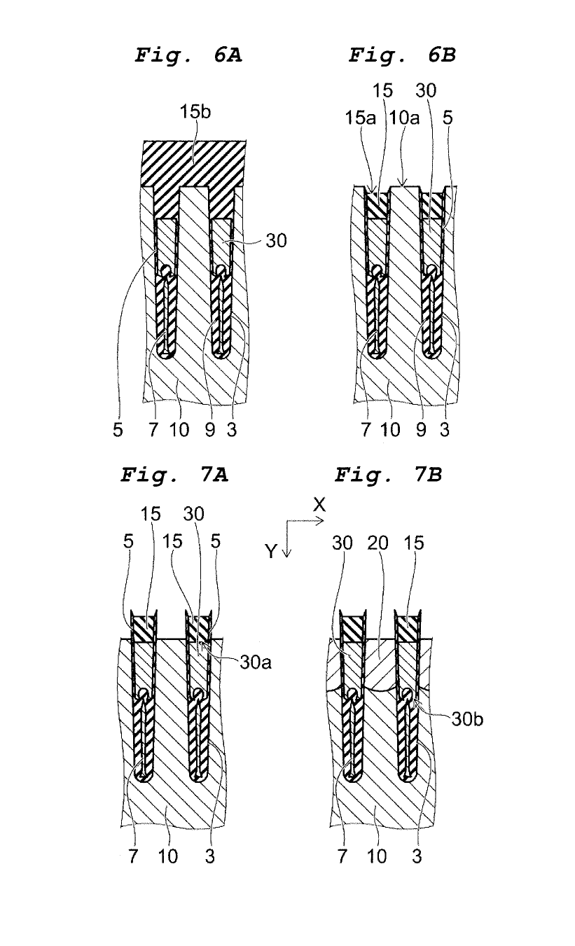

Next, as shown in FIG. 6A, an insulating film 15b (second insulating film) is filled into each space 3c above the gate electrode 30. The insulating film 15b may be, for example, a silicon oxide film and can be formed by the CVD method using TEOS (tetraethoxysilane).

Next, as shown in FIG. 6B, for example, the insulating film 15b is etched back using the RIE method to leave behind the insulating film 15 embedded into each space 3c. In other words, the amount of etching is controlled so that the upper surface 15a of the insulating film 15 is at about the same position as the upper surface 10a of the n type semiconductor layer 10.

In addition, the upper surface 15a of the insulating film 15 is wet-etched, e.g., using an etching solution containing diluted fluoric acid so that the etching rate is slower in the silicon oxide film formed by the thermal oxidation than in the silicon oxide film formed by the CVD method. In other words, when such etching solution is used, the etching rate of the gate insulating film 5 becomes slower than the etching rate of the insulating film 15. As a result, after wet-etching, the upper surface 15a of the insulating film 15 is below the upper end 5a of the gate insulating film 5 extending along the wall surface of the trench 3. In other words, the upper end 5a of the gate insulating film 5 protrudes above the upper surface 15a of the insulating film 15.

Next, as shown in FIG. 7A, the n type semiconductor layer 10 between the adjacent trenches 3 is etched to a depth near the upper end 30a of the gate electrode 30. For example, using the RIE method, etching is carried out under the condition of a 1:7 selection ratio of the silicon oxide film to silicon.

Next, as shown in FIG. 7B, the p type base region 20 is formed in the depth direction (Y direction) from the upper surface 10a of the n type semiconductor layer 10. For example, boron (B) as p type impurities are ion-implanted into the upper surface 10a of the n type semiconductor layer 10. Thereafter, the boron is activated by applying a heat treatment and diffused in the Y direction. The concentration of the p type impurities of the p type base region may be, for example, 5×10¹⁶ to 5×10¹⁷ cm⁻³.

The p type base region 20 is formed to extend from a depth associated with the upper surface 10a of the n type semiconductor layer 10 to a depth which is below the upper end 30a and above the lower end 30b of the gate electrode 30. In other words, the p type base region 20 does not extend below the lower end 30b of the gate electrode 30.

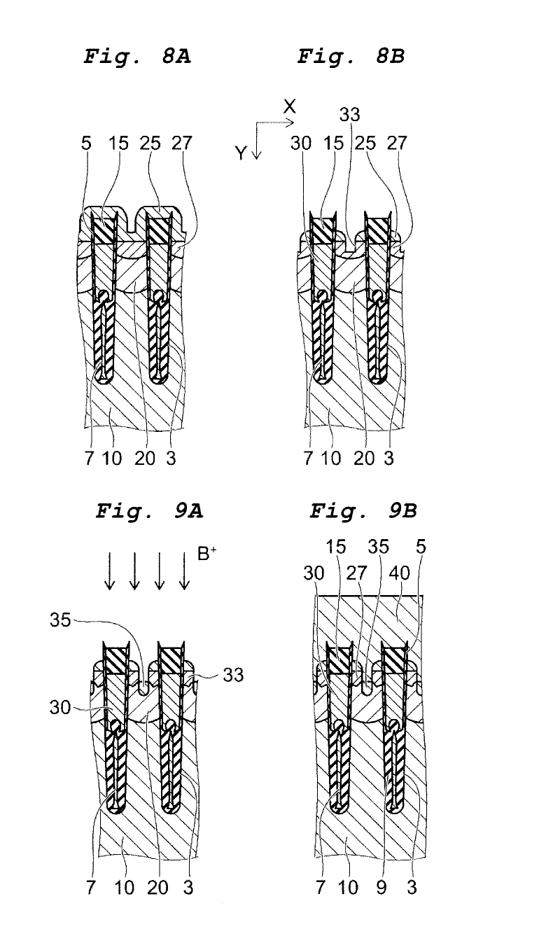

Next, as shown in FIG. 8A, an n type polysilicon layer 25 (conductive layer) containing n type impurities such as phosphorus (P) is formed. The n type polysilicon layer 25 covers the surface of the insulating film 15, gate insulating film 5, and p type base region 20. In this process, the n type impurities, which are included in the n type polysilicon layer 25, are diffused into the upper portions of the p type base region 20, forming the n type source region 27. During this diffusion step, the n type impurities are diffused up to a depth below the upper end 30a of the gate electrode 30. Therefore, the n type source region 27 opposite to the gate electrode 30 is formed via the gate insulating film 5. In other words, during the etching process of the n type semiconductor layer 10 shown in FIG. 7A, the position of the upper surface 10a of the n type semiconductor layer 10 after etching is controlled in consideration of the expected diffusion depth of the n type impurities during the process of forming the n type polysilicon layer 25.

Next, as shown in FIG. 8B, the n type polysilicon layer 25 is etched back to form contact hole 33 at the center of the n type source region 27. The n type polysilicon layer 25, for example, is formed by the RIE method under the condition in which the etching rate in the depth direction (Y direction) is faster than that in the horizontal direction (X direction). At that time, the entire surface of the n type polysilicon layer 25 is etched, but the part formed on the side surface of the gate insulating film 5 becomes a mask for etching of the n type source region 27. In other words, in an area centered between adjacent trenches 3 in which the thickness of the n type polysilicon layer 25 is thin in the Y-direction, the n type polysilicon layer 25 is completely etched back, and further etching of the n type source region 27 thus takes place. On the other hand, the n type polysilicon layer 25 formed on the side surface of the gate insulating film 5 is not completely etched back, and the n type source region 27 below the n type polysilicon layer 25 is also retained.

Therefore, the contact hole 33 can be formed at the center of the n type source region 27 by the self-alignment utilizing the step difference between the insulating film 15 installed in the upper part of the trench 3 and the n type source region 27.

Next, as shown in FIG. 9A, p type impurities such as boron (B) are ion-implanted into the bottom face of the contact hole 33 to form the p type contact region 35. Subsequently, the p type impurity concentration in the p type contact region 35 may be, for example, 1×10¹⁸ to 5×10¹⁸ cm⁻³, which may be higher than the p type impurity concentration of the p type base region 20. In addition, the p type contact region 35 is formed as a p type region connected to the p type base region 20.

Next, as shown in FIG. 9B, the source electrode 40 is formed so as to cover the insulating film 15 and the gate insulating film 5 and make contact with the p type contact region 35 and the n type source region 27. The source electrode 40 extends downwards to the insides of the contact holes 33. As a result, a so-called trench contact structure in which the source electrode 40 makes contact with the p type contact region 35 formed on the bottom face of the contact holes 33 and the n type source region 27 exposed to the side surface, is formed. The drain electrode 50 (depicted in FIG. 1) is then formed on the lower surface of the n type semiconductor layer 10 (n type drift layer), completing the wafer process (see FIG. 1).

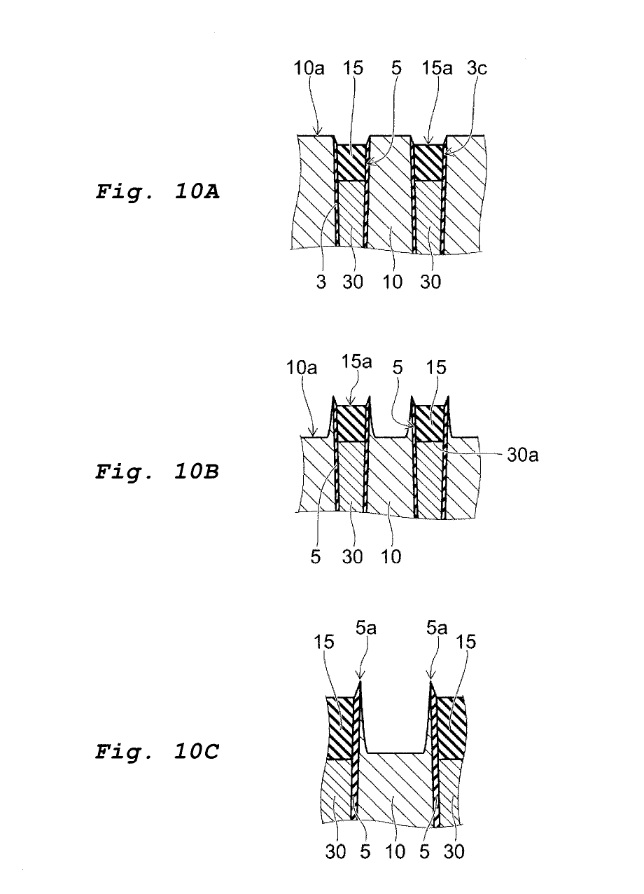

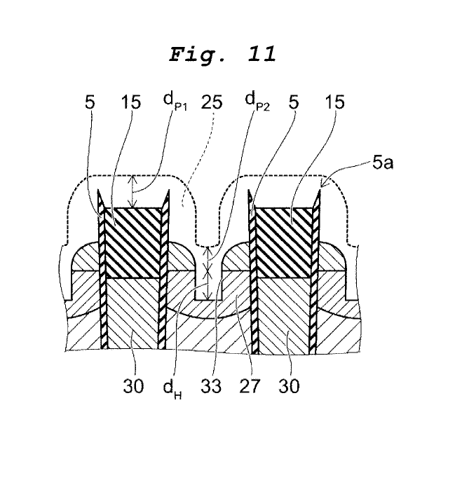

FIGS. 10A to 10C are schematic diagrams showing a wafer cross-section of the semiconductor device 100 during manufacturing. FIG. 10A is a cross-section of the semiconductor device 100 showing a state in which the insulating film 15 is formed in the space 3c of the upper part of the trench 3. FIG. 10B is a cross-section of the semiconductor device 100 showing a state in which the n type semiconductor layer 10 between adjacent trenches 3 is etched. FIG. 10C is an enlarged view of the cross-section of the semiconductor device 100 between the insulating films 15.

As shown in FIG. 10A, the insulating film 15 is installed on the gate electrode 30 in the trench 3. Next, the upper surface 15a of the insulating film 15 is formed at a position slightly lower than the upper surface 10a of the n type semiconductor layer 10.

As shown in FIG. 10B, after etching, the upper surface 10a of the n type semiconductor layer 10 is at a depth near the upper surface 30a of the gate electrode 30. In addition, both side parts of the insulating film 15, i.e., gate insulating film 5, protrude upward from its upper surface 15a.

As depicted in FIG. 10C, the gate insulating film 5 extends upward along the side surface of the insulating film 15, and its upper end 5a protrudes above the upper surface 15a of the insulating film 15.

In case the n type polysilicon layer 25 is formed on the insulating film 15 and the gate insulating film 5 having this structure, the film thickness of the n type polysilicon layer 25, which is formed on the insulating film 15, is increased compared with the case in which there is no protruded part, due to the effect of the parts protruded and installed at both sides of the insulating film 15. When thickness is increased in this manner, the etching-back time of the n type polysilicon layer 25 formed on the insulating film 15 can be lengthened.

FIG. 11 is a schematic cross-section of the semiconductor device 100 showing a process of etching the n type polysilicon layer 25 during manufacturing. The surface of the n type polysilicon layer 25, which covers the insulating film 15 and the gate insulating film 5 before etching, is indicated by a broken line.

In the etching process of the n type polysilicon layer 25, its etching time is limited by the thickness d_{P1} of the n type polysilicon layer 25 formed on the insulating film 15. In other words, after the n type polysilicon layer 25 formed on the insulating film 15 is completely removed, if etching is continued, the thickness of the insulating film 15 is decreased, lowering the dielectric voltage between the gate and the source. For this reason, it is not preferable to continue etching after the n type polysilicon layer 25 on the insulating film 15 has been completely etched back.

On the other hand, between adjacent trenches 3, after etching back the n type polysilicon layer 25 that is on the n type source region 27, the n type source region 27 is etched to selectively form the contact hole 33. For this reason, etching is continued even after the n type polysilicon layer 25 has been completely etched back.

In summary, when the portion of the n type polysilicon layer 25 above the n type source region 27 has been completely etched back, it is desirable for a portion of the n type polysilicon layer 25 to remain above the insulating film 15. In other words, it is desirable for the thickness d_{P1} of the n type polysilicon layer 25 formed on the insulating film 15 to be greater than the thickness d_{P2} of the n type polysilicon layer 25 formed on the n type source region 27. In addition, as the difference between d_{P1} and d_{P2} increases, the etching time of the n type source region 27 can be lengthened, thus enabling a deepening of the depth d_{H} of the contact hole 33.

In this embodiment, the upper end 5a of the gate insulating film 5 extending along the side surface of the insulating film 15 protrudes upward from the upper surface of the insulating film 15. Therefore, the thickness d_{P1} of the n type polysilicon layer 25, which is formed on the insulating film 15, is greater than that of the case where the upper end 5a of the gate insulating film 5 is at the same position as the upper surface of the insulating film 15 or is lower than that. On the other hand, the thickness d_{P2} of the n type polysilicon layer 25 on the n type source region 27 does not depend upon the position of the upper end 5a of the gate insulating film 5. Therefore, the thickness d_{P1} of the n type polysilicon layer 25, which is formed on the insulating film 15, can be greater than the thickness d_{P2} of the n type silicon layer 25 which is formed on the n type source region 27, thus being able to deepen the contact hole 33.

As mentioned above, in this embodiment, in the process for forming the contact hole 33 by the self-alignment, the n type polysilicon layer 25, which is formed on the insulating film 15, is formed thick. Next, the contact hole 33 is formed deep, and the p type contact region 35 can be formed at a deep position. Therefore, the discharge resistance in discharge path of holes via the p type contact region 35 can be lowered. In addition, the holes accumulated in the p type base region 20 are smoothly discharged to the source electrode 40, so that the switching characteristic is improved, thereby being able to reduce the switching loss.

Moreover, since the holes generated in the n type drift layer 10 are also efficiently discharged, the avalanche withstand voltage is also improved. Furthermore, the turn-on of a parasitic transistor between the p type base region 20 and the n type drift layer 10, and n type source region 27 is suppressed to prevent latch-up.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of embodiments described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device, comprising the steps of:
forming a first insulating film on inner surfaces of trenches arranged in parallel in a semiconductor layer of a first conductive type;
forming a control electrode on the first insulating film in each of the trenches;
forming a second insulating film on the control electrode, such that an upper surface of the second insulating film is at a position lower than an upper end of the first insulating film;
etching the semiconductor layer between adjacent trenches to a depth near an upper end of the control electrode;
forming a first semiconductor region of a second conductive type from a surface of the semiconductor layer;
forming a conductive layer of the first conductive type that covers the first insulating film, the second insulating film, and the first semiconductor region, from which impurities are diffused into the upper portion of the first semiconductor region to form a second semiconductor region of the first conductive type; and
etching back the conductive layer of the first conductive type and the second semiconductor region to form a contact hole in the second semiconductor region.

2. The method of claim 1, further comprising the steps of:
forming a third semiconductor region of the second conductive type on a surface of the second semiconductor region exposed by the contact hole; and
forming a main electrode for covering the first insulating film and the second insulating film in contact with the second semiconductor region and the third semiconductor region.

3. The method of claim 1, wherein
the semiconductor layer is a silicon layer; and
the first insulating film is a silicon oxide film that is thermally grown from the semiconductor layer.

4. The method of claim 1, wherein the conductive layer is etched back anisotropically.

5. The method of claim 4, wherein the conductive layer is etched back anisotropically using reactive ion etching.

6. The method of claim 1, wherein the conductive layer remains on either side of the contact hole after the conductive layer is etched and the second semiconductor region is etched to form the contact hole.

7. The method of claim 6, further comprising the step of:
implanting impurities into a surface of the second semiconductor region exposed by the contact hole to form a third semiconductor region of the second conductive type.

8. The method of claim 1, wherein the first semiconductor region is formed to a depth between an upper end of the control electrode and a lower end of the control electrode.

9. A semiconductor device, comprising:
a semiconductor layer of a first conductive type;
a first semiconductor region of a second conductive type on the semiconductor layer;
a first insulating film and a control electrode disposed in a trench formed in the semiconductor layer through the first semiconductor region, the first insulating film being formed on an inner surface of the trench and the control electrode being formed on the first insulating film; and
a second insulating film on the control electrode, the upper surface of the second insulating film being lower than an upper end of the first insulating film.

10. The semiconductor device of claim 9, further comprising:
a second semiconductor region formed on the first semiconductor region on an opposite side of the first insulating film from the control electrode,
wherein an upper surface of the first insulating film is above an upper surface of the control electrode.

11. The semiconductor device of claim 10, further comprising:
a third semiconductor region formed above and connected to the first semiconductor region; and
a main electrode in contact with the second semiconductor region and the third semiconductor region.

12. The semiconductor device of claim 11, wherein the main electrode extends into a contact hole formed between adjacent control electrodes to make contact with the third semiconductor region.

13. The semiconductor device of claim 12, further comprising:
a conductive layer on either side of the main electrode that extends into the contact hole, the conductive layer being formed on an opposite side of the first insulating film from the control electrode.

14. The semiconductor device of claim 9, further comprising:
a field plate electrode disposed in the trench below the control electrode.

15. A semiconductor device, comprising:
a semiconductor layer of a first conductive type;
a first semiconductor region of a second conductive type on the semiconductor layer;
a first insulating film and a control electrode disposed in a trench formed in the semiconductor layer through the first semiconductor region;
a second insulating film on the control electrode;
a second semiconductor region formed on the first semiconductor region on an opposite side of the first insulating film from the control electrode;
a third semiconductor region formed above and connected to the first semiconductor region;
a main electrode in contact with the second semiconductor region and the third semiconductor region and extending into a contact hole formed between adjacent control electrodes to make contact with the third semiconductor region; and
a conductive layer on either side of the main electrode that extends into the contact hole and above the second semiconductor region.

16. The semiconductor device of claim 15, wherein the conductive layer is isolated from the control electrode by the first insulating film.

17. The semiconductor device of claim 16, wherein an upper surface of the first insulating film is above an upper surface of the control electrode.

18. The semiconductor device of claim 17, wherein the first semiconductor region is formed to a depth between an upper end of the control electrode and a lower end of the control electrode.

19. The semiconductor device of claim 15, wherein the upper surface of the second insulating film is lower than an upper end of the first insulating film.

20. The semiconductor device of claim 15, further comprising:
a field plate electrode disposed in the trench below the control electrode.
